(19) United States
(12) Patent Application Publication
(10) Pub. No.: US 2007/0047303 A1
(43) Pub. Date: Mar. 1, 2007

(54) Electrically erasable programmable read-only memory cell transistor and related method

(76) Inventor: Jun-Seuck Kim, Seoul (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/493,583

(22) Filed: Jul. 27, 2006

(30) Foreign Application Priority Data
Aug. 25, 2005 (KR) 2005-0078166

(51) Int. Cl. G11C 16/04

(52) U.S. Cl. 365/185.05

(57) ABSTRACT

An electrically erasable programmable read-only memory (EEPROM) cell transistor and a method of fabricating the EEPROM cell transistor are provided. The EEPROM cell transistor comprises a semiconductor substrate; a first tunnel oxide layer formed on the semiconductor substrate; and a first floating gate electrode formed on the first tunnel oxide layer and adapted to store charge that tunnels through the first tunnel oxide layer. The EEPROM cell transistor further comprises a second tunnel oxide layer formed on the first floating gate electrode; a second floating gate electrode formed on the second tunnel oxide layer and adapted to store charge that tunnels from the first floating gate electrode through the second tunnel oxide layer, wherein the second floating gate electrode is formed from a phase changeable material; a gate insulating layer formed on the second floating gate electrode; and a control gate electrode formed on the gate insulating layer.

### BACKGROUND OF THE INVENTION

1. Field of the Invention

Embodiments of the invention relate to a nonvolatile semiconductor memory device and a method for fabricating the nonvolatile semiconductor memory device. In particular, embodiments of the invention relate to an electrically erasable programmable read-only memory (EEPROM) cell transistor comprising two floating gate electrodes, wherein at least one of the floating gate electrodes is formed from a phase changeable material, and a method of fabricating the EEPROM cell transistor.

This application claims priority to Korean Patent Application No. 10-2005-0078166, filed Aug. 25, 2005, the subject matter of which is hereby incorporated by reference in its entirety.

2. Description of Related Art

There is a continuing commercial demand for highly-integrated electrically erasable programmable read-only memory (EEPROM) devices adapted for use within various host devices such as computers, telecommunications devices, and consumer electronics. Many of these host devices include a hard disk apparatus adapted for use as an auxiliary memory. Conventional hard disk apparatuses include a rotating magnetic disk. However, in portable computational devices, such as PDA's and notebook computers, the hard disk apparatus occupies a great deal of available space. Thus, the ongoing effort to replace conventional hard disk apparatuses with much smaller, highly-integrated, high-performance EEPROM continues.

One criterion motivating the design of emerging EEPROM is further reductions in its size. Previously, this criterion motivated the development of the so-called “NAND cell structure.” An EEPROM device having a NAND cell structure may have relatively fewer select transistors per unit cell and relatively fewer connection openings relative to constituent bit lines, as compared with other EEPROM cell structures.

An exemplary cell transistor for a NAND cell structure is disclosed in an article entitled, “New Device Technologies for 5V Only 4 Mb EEPROM with NAND Structure Cell,” 1988 IEDM at pages 412-415. The subject matter of this article hereby incorporated by reference into this Background. As disclosed in this article, a unit EEPROM cell transistor for a NAND cell structure comprises a floating gate electrode and a control gate electrode.

One example of a conventional EEPROM cell transistor will be described in some additional detail with reference to Figure (FIG.) 1 which shows a cross-sectional view of the conventional EEPROM cell transistor.

As illustrated in FIG. 1, the conventional EEPROM cell transistor includes a semiconductor substrate 10 having an active region 2, and active region 2 comprises a channel region 4. The conventional EEPROM cell transistor also includes a tunnel oxide layer 12 formed with a predetermined thickness on semiconductor substrate 10, a floating gate electrode 14 formed on tunnel oxide layer 12, and a gate insulating layer 16 formed on floating gate electrode 14. The conventional EEPROM cell transistor still also includes a control gate electrode 18 formed on gate insulating layer 16, a gate upper insulating layer 20 formed on control gate electrode 18, and a spacer 22 formed on the sidewall of a gate stack comprising floating gate electrode 14 and control gate electrode 18.

Though not shown in the drawings, the conventional EEPROM cell transistor may also include pad contact electrodes, wherein a pad contact electrode is formed on each side of the gate stack and each pad contact electrode is adjacent to a spacer 22 and is electrically connected to a source/drain region of semiconductor substrate 10.

The conventional EEPROM cell transistor of FIG. 1 stores charge passing horizontally from channel region 4 disposed below the gate stack and between the source/drain regions in floating gate electrode 14. The conventional EEPROM cell transistor of FIG. 1 stores charge on floating gate electrode 14. The charge stored on floating gate electrode 14 “tunnels” through tunnel oxide layer 12 under the influence of a coulomb force induced by an electric field corresponding to the voltage applied via control gate electrode 18. Floating gate electrode 14 may be formed, for example, from a conductive layer formed from doped polysilicon or a metal, such as tungsten, aluminum, or titanium.

Charge tunneling through tunnel oxide layer 12 may be stored on floating gate electrode 14, or it may return to channel region 4 in correlation to the applied gate voltage.

When charge is stored on floating gate electrode 14, and a predetermined voltage is applied to control gate electrode 18, a bias voltage between the source/drain regions of the conventional EEPROM cell transistor of FIG. 1 may vary instantaneously.

However, when charge is stored on floating gate electrode 14 and a predetermined voltage is applied to control gate electrode 18, the bias voltage between the source/drain regions does not vary.

Thus, 1 bit of data may be stored in the conventional EEPROM cell transistor of FIG. 1 in accordance with the presence of charge stored on floating gate electrode 14, as it is formed between channel region 4 and control gate electrode 18.

However, the conventional EEPROM cell transistor of FIG. 1 is not able to store more than 1 bit of data in accordance with presence of stored charge on floating gate electrode 14. Thus, the storage capacity of the conventional EEPROM cell transistor of FIG. 1 is less than a cell transistor capable of storing 2 or more bits of data.

Further, though conventional technology for storing 2 or more bits of data in an EEPROM cell transistor is widely known, the conventional technology is limited to EEPROM cell transistors wherein the floating gate electrode is formed from doped polysilicon. In addition, the operation of reading data stored in the conventional EEPROM cell transistor through a sense amplifier or page buffer is relatively complicated.

### SUMMARY OF THE INVENTION

Therefore, embodiments of the invention provide an electrically erasable programmable read-only memory (EEPROM) cell transistor having an increased data storage capacity of 2 or more bits of data, wherein the EEPROM cell transistor comprises a floating gate electrode formed from a phase changeable material or a conductive layer, and a related operation for reading data from the EEPROM cell transistor through a sense amplifier or page buffer which is simpler than those proposed in relation to conventional EEPROM cell transistors.

In one embodiment, the invention provides an EEPROM cell transistor comprising; a first tunnel oxide layer disposed on a semiconductor substrate; and a first floating gate electrode disposed on the first tunnel oxide layer and adapted to store charge that tunnels through the first tunnel oxide layer. The EEPROM cell transistor further comprises a second tunnel oxide layer disposed on the first floating gate electrode; a second floating gate electrode disposed on the second tunnel oxide layer and adapted to store charge that tunnels from the first floating gate electrode through the second tunnel oxide layer, wherein the second floating gate electrode is disposed from a phase changeable material; a gate insulating layer disposed on the second floating gate electrode; and a control gate electrode disposed on the gate insulating layer.

In another embodiment, the invention provides a method for fabricating an EEPROM cell transistor that comprises forming a first tunnel oxide layer on a semiconductor substrate; forming a first floating gate electrode on the first tunnel oxide layer, wherein the first floating gate electrode is formed from a phase changeable material or metal; and forming a second tunnel oxide layer on the first floating gate electrode. The method further comprises forming a second floating gate electrode on the second tunnel oxide layer, wherein the second floating gate electrode is formed from a phase changeable material; forming a gate insulating layer on the second floating gate electrode; and forming a control gate electrode on the gate insulating layer.

### BRIEF DESCRIPTION OF THE DRAWINGS

Embodiments of the invention will be described herein with reference to the accompanying drawings, in which like reference symbols refer to like elements throughout. For purposes of clarity, the thicknesses of layers and regions in the drawings may not be drawn to scale. In the drawings:

FIG. 1 is a cross-sectional view illustrating the structure of a conventional electrically erasable programmable read-only memory (EEPROM) cell transistor;

FIG. 2 is a cross-sectional view illustrating the structure of an EEPROM cell transistor in accordance with an embodiment of the invention;

FIGS. 3A through 3I are cross-sectional views illustrating fabrication steps in a method for fabricating the EEPROM cell transistor of FIG. 2 in accordance with an embodiment of the invention;

FIG. 4 is a cross-sectional view illustrating the structure of an EEPROM cell transistor in accordance with another embodiment of the invention; and,

FIGS. 5A through 5I are cross-sectional views illustrating fabrication steps in a method for fabricating the EEPROM cell transistor of FIG. 4 in accordance with an embodiment of the invention.

### DESCRIPTION OF EMBODIMENTS

As used herein, when a first element is said to be “on” a second element, the first element may be directly on the second element, or intervening elements may be present.

FIG. 2 is a cross-sectional view illustrating the structure of an electrically erasable programmable read-only memory (EEPROM) cell transistor in accordance with an embodiment of the invention.

As illustrated in FIG. 2, an EEPROM cell transistor 200 comprises a semiconductor substrate 100 having an active region 102 defined by an electrically insulated isolation layer (not shown) or an electrically insulated field oxide layer (not shown). Also, active region 102 comprises a channel region 104. EEPROM cell transistor 200 further comprises a first tunnel oxide layer 112 having a predetermined thickness and formed on semiconductor substrate 100, a first floating gate electrode 114 formed from a phase changeable material (e.g., GeSeTe) and formed on first tunnel oxide layer 112, and a second tunnel oxide layer 116 formed on first floating gate electrode 114. EEPROM cell transistor 200 still further comprises a second floating gate electrode 118 formed on second tunnel oxide layer 116 and formed from a phase changeable material (e.g., GeSeTe), a gate insulating layer 120 formed on second floating gate electrode 118, a control gate electrode 122 formed on gate insulating layer 120, and an upper insulating layer 124 having a predetermined thickness formed on control gate electrode 122. EEPROM cell transistor 200 further comprises spacers 126 formed on both sidewalls of a gate stack 140 comprising first and second floating gate electrodes 114 and 118, control gate electrode 122, first and second tunnel oxide layers 112 and 116, gate insulating layer 120, and upper insulating layer 124.

Though not shown in the drawings, a pad contact electrode may be formed on each side of gate stack 140, wherein each pad contact electrode is adjacent to a spacer 126 and is electrically connected to a source/drain region of EEPROM cell transistor 200 formed in active region 102.

In the embodiment illustrated in FIG. 2, first floating gate electrode 114 and second floating gate electrode 118 are each formed from the phase changeable material. The state of the phase changeable material can be changed in accordance with a voltage applied to control gate electrode 122. The phase changeable material may be, for example, a GeSe compound semiconductor material or a GeSeTe compound semiconductor material. A suitable phase changeable material is disclosed, for example, in published U.S. Patent App. No. 2005/0051901, the subject matter of which is hereby incorporated by reference in its entirety.

Generally, a phase changeable material is a material that may be changed between an amorphous state and a crystalline state under predetermined conditions. In particular, the phase changeable material is changed to the amorphous state or to the crystalline state in accordance with an applied voltage or current and the amount of time for which the voltage or current is applied, wherein the applied voltage or current has a level that is greater than or equal to a predetermined level. For example, the GeSe or GeSeTe compound semiconductor material is changed from a crystalline state to an amorphous state (i.e., “reset”) when a reset voltage, using a reset pulse type and having a predetermined reset voltage level, is applied to the GeSe or GeSeTe compound semiconductor material for a relatively short amount of time (i.e., on the order of several nanoseconds). When a set voltage, using a set pulse type and having a set voltage level that is lower than the reset voltage level, is applied to the GeSe or GeSeTe compound semiconductor material in the amorphous state for a relatively long amount of time (i.e., on the order of tens of nanoseconds), the GeSe or GeSeTe compound semiconductor material is changed from an amorphous state to a crystalline state.

As used herein, when a phase changeable material is said to be “set,” it means that the phase changeable material is changed from an amorphous state to a crystalline state, and when a phase changeable material is said to be “reset,” it means that the phase changeable material is changed from a crystalline state to an amorphous state.

Further, the voltage level of the set voltage or reset voltage necessary to change the state of the phase changeable material will vary with the composition ratio of the compound semiconductor material. For the various composition ratios, the voltage level of the set or rest voltages, as applied to control gate electrode 122, may be empirically determined.

In an amorphous state, the phase changeable material may function as a dielectric layer (i.e., as an electrical insulator) since molecular bonds and paths for charge are broken when the phase changeable material is reset, so a phase changeable material in an amorphous state is less conductive than a phase changeable material in a crystalline state. On the contrary, when the phase changeable material is in a crystalline state, the phase changeable material may function as a conductive layer (i.e., as an electrical conductor) since molecular bonds and paths for charge are formed when the phase changeable material is set, so a phase changeable material in a crystalline state is more conductive than a phase changeable material in an amorphous state.

Further, when the phase changeable material of first floating gate electrode 114 is in a crystalline state, first floating gate electrode 114 can store charge (for example, electrons) that tunnel from channel region 104 formed below gate stack 140 through first tunnel oxide layer 112 as a result of the gate voltage applied to control gate electrode 122. Also, when the phase changeable material of second floating gate electrode 118 is in a crystalline state, second floating gate electrode 118 can store charge (for example, electrons) that tunnel from channel region 104 formed below gate stack 140 through first and second tunnel oxide layers 112 and 116 as a result of the gate voltage applied to control gate electrode 122.

In an exemplary data storage scheme for EEPROM cell transistor 200, when no charge are stored in either of first and second floating gate electrodes 114 and 118, EEPROM cell transistor 200 is storing a data value of “00,” and when charge are stored only in first floating gate electrode 114, EEPROM cell transistor 200 is storing a data value of “01.”When charge are stored only in second floating gate electrode 118, EEPROM cell transistor 200 is storing a data value of “10,” and when charge are stored in both of first and second floating gate electrodes 114 and 118, EEPROM cell transistor 200 is storing a data value of “11.” Thus, used together, first and second floating gate electrodes 114 and 118 can store 2 bits of information.

Therefore, EEPROM cell transistor 200, which comprises first and second floating gate electrodes 114 and 118 that each comprise the phase changeable material, can store 2 or more bits of information, thereby improving data storage capacity.

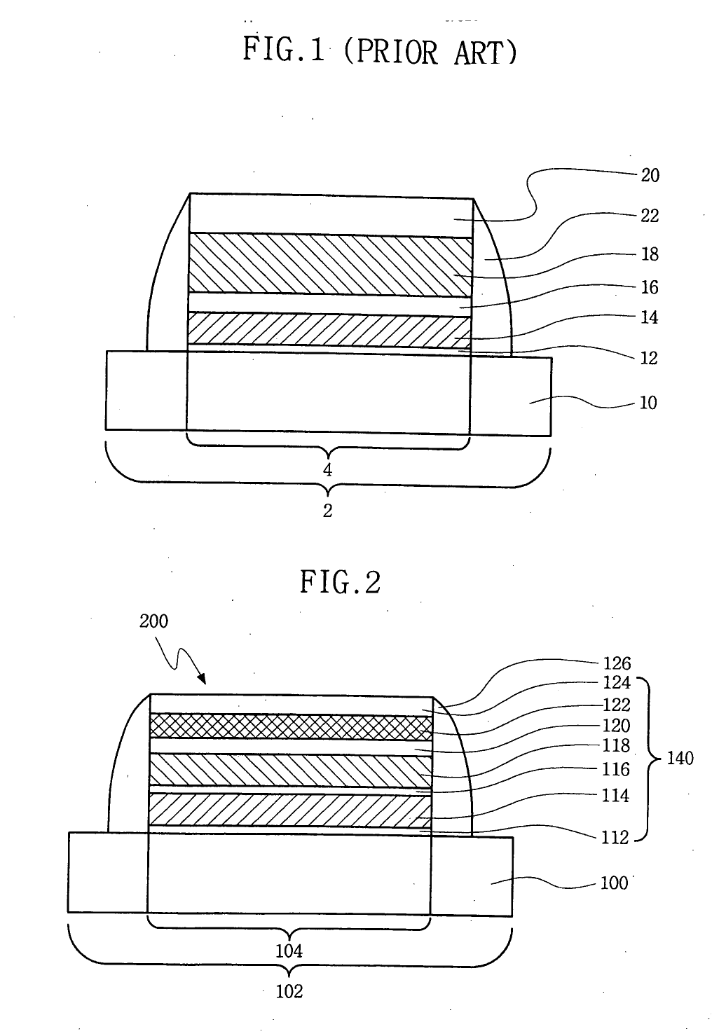

Further, first and second floating gate electrodes 114 and 118, which are formed on channel region 104, each comprise a phase changeable material for storing a plurality of charge, so the material from which first and second floating gate electrodes 114 and 118 are formed is not limited to polysilicon doped with conductive impurities, unlike floating gate electrode 14 of the conventional EEPROM cell transistor of FIG. 1. In addition, a process for reading data from EEPROM cell transistor 200 through a sense amplifier or page buffer can be simplified in comparison to the corresponding process for the conventional EEPROM cell transistor of FIG. 1.

Further, first tunnel oxide layer 112 formed between active region 102 and first floating gate electrode 114, second tunnel oxide layer 116 formed between first floating gate electrode 114 and second floating gate electrode 118, and gate insulating layer 120 formed between second floating gate electrode 118 and control gate electrode 122 are each formed from respective dielectric layers, such as silicon oxide layers, that are adapted to pass the electric field induced by a voltage applied to control gate electrode 122.

First tunnel oxide layer 112 is disposed further from control gate electrode 122 than second tunnel oxide layer 116, and second tunnel oxide layer 116 is disposed further from control gate electrode 122 than gate insulating layer 120. Since the intensity of an electric field decreases as it passes through each of gate insulating layer 120, second tunnel oxide layer 116, and first tunnel oxide layer 112, which are each disposed sequentially further from control gate electrode 122, as described above, gate insulating layer 120, second tunnel oxide layer 116, and first tunnel oxide layer 112 are formed such that gate insulating layer 120 is thicker than second tunnel oxide layer 116, and second tunnel oxide layer 116 is thicker than first tunnel oxide layer 112. For example, first tunnel oxide layer 112 may be formed having a thickness of about 10 to 30 Å, second tunnel oxide layer 116 may be formed having a thickness of about 30 to 80 Å, and gate insulating layer 120 may be formed having a thickness of about 50 to 120 Å.

Further, first and second floating gate electrodes 114 and 118 may be formed having different thicknesses so that first and second floating gate electrodes 114 and 118 may store different amounts of charge. For example, first floating gate electrode 114 may be formed with a thickness of about 50 to 500 Å, and second floating gate electrode 118 may be formed with a thickness of about 30 to 400 Å.

Further, a predetermined voltage may be applied to control gate electrode 122 to permit charge stored in first and second floating gate electrodes 114 and 118 to tunnel to channel region 104. Also, the data stored in first and second floating gate electrodes 114 and 118 can be read in accordance with a voltage applied between the source/drain regions of EEPROM cell transistor 200.

In addition, when, for example, the phase changeable material of first floating gate electrode 114 is in a crystalline state, charge can be stored in first floating gate electrode 114 by applying a predetermined first voltage (e.g., a positive voltage) to control gate electrode 122 and permitting charge (e.g., electrons) to tunnel from channel region 104 into first floating gate electrode 114 through first tunnel oxide layer 112. Then, the charge can be selectively stored in second floating gate electrode 118 by applying a second voltage higher than the first voltage to control gate electrode 122 and allowing the charge stored in first floating gate electrode 114 to tunnel through second tunnel oxide layer 116 and into second floating gate electrode 118. When charge are moved from first floating gate electrode 114 to second floating gate electrode 118, the phase changeable material of each of first and second floating gate electrodes 114 and 118 must be in a crystalline state. Thus, when storing data in EEPROM cell transistor 200 by selectively storing charge in second floating gate electrode 118, or when selectively moving (i.e., applying) the charge stored in second floating gate electrode 118 to channel region 104 by causing the charge stored in second floating gate electrode 118 to tunnel through second tunnel oxide layer 116, first floating gate electrode 114, and first tunnel oxide layer 112, the phase changeable material of first floating gate electrode 114 must be in a crystalline state.

However, when storing data by selectively storing charge in first floating gate electrode 114, the phase changeable material of second floating gate electrode 118 must be in an amorphous state so that the electric field induced by the voltage applied to control gate electrode 122 passes through second floating gate electrode 118 and reaches first floating gate electrode 114 directly. That is, when the phase changeable material of second floating gate electrode 118 is in a crystalline state, data selectively stored in first floating gate electrode 114 cannot be readily read because the electric field induced by the first voltage applied to control gate electrode 122 reaches first floating gate electrode 114 only after passing through second floating gate electrode 118, which is acting as a conductive layer.

Therefore, the phase changeable material of first floating gate electrode 114 must be in a crystalline state in order to write data by storing charge to second floating gate electrode 118, or to read data using the charge stored in second floating gate electrode 118.

Further, the phase changeable material of second floating gate electrode 118 must be in an amorphous state in order to store charge in first floating gate electrode 114, or to allow the charge stored in first floating gate electrode 114 to tunnel through first tunnel oxide layer 112 to channel region 104.

In addition, a first reset voltage used to reset the phase changeable material in first floating gate electrode 114 may have substantially the same voltage level as a second reset voltage used to reset the phase changeable material in second floating gate electrode 118.

Control gate electrode 122 is formed from a conductive layer so that it will transfer the voltage externally applied to it, or applied to it from a control device. For example, control gate electrode 122 comprises at least one material selected from the group consisting of polysilicon doped with conductive impurities, tungsten (W), aluminum (Al), and titanium (Ti).

Though it is not shown in FIG. 2, control gate electrode 122 may be formed such that it is electrically connected to second floating gate electrode 118 via material formed in a contact hole formed in gate insulating layer 120 to expose a portion of second floating gate electrode 118. If such a contact hole is formed, a material that fills the inside of the contact hole to electrically connect control gate electrode 122, which is formed from a conductive layer, and second floating gate electrode 118, which is formed from the phase changeable material, may be the same as the material deposited during the formation of control gate electrode 122. Alternatively, a separate process for forming a contact plug may be performed in which a conductive layer deposited inside the contact hole is planarized to form a contact plug adapted to electrically connect control gate electrode 122 and second floating gate electrode 118. In order to improve electrical characteristics of the connection between control gate electrode 122 and second floating gate electrode 118, the contact plug may be formed from silver (Ag), for example, which has excellent conductivity.

Second floating gate electrode 118, which may be electrically connected to control gate electrode 122, comprises a phase changeable material that may change between an amorphous state and a crystalline state in accordance with a voltage applied to control gate electrode 122. As described above, second floating gate electrode 118 must function as a dielectric layer and be in an amorphous state in order to selectively store charge to first floating gate electrode 114, or to allow charge to tunnel from first floating gate electrode 114 to channel region 104 through first tunnel oxide layer 112. Second floating gate electrode 118 may be formed from a phase changeable material that can be set when a second set voltage having at least a second set voltage level is applied to it for a relatively longer period of time, wherein the phase changeable material of first floating gate electrode 114 can be set when a first set voltage having at least a first set voltage level is applied to it, and the second set voltage level is greater than the first set voltage level (i.e., a predetermined voltage).

Because EEPROM cell transistor 200 comprises first and second floating gate electrodes 114 and 118 that are formed between active region 102 and control gate electrode 122, are insulated from one another, and are each formed from a phase changeable material, EEPROM cell transistor 200 can store 2 or more bits of data. Therefore, the data storage capacity of EEPROM cell transistor 200 may be improved relative to a conventional EEPROM cell transistor.

A method of fabricating EEPROM cell transistor 200 of FIG. 2, in accordance with an embodiment of the invention, will be described hereinafter.

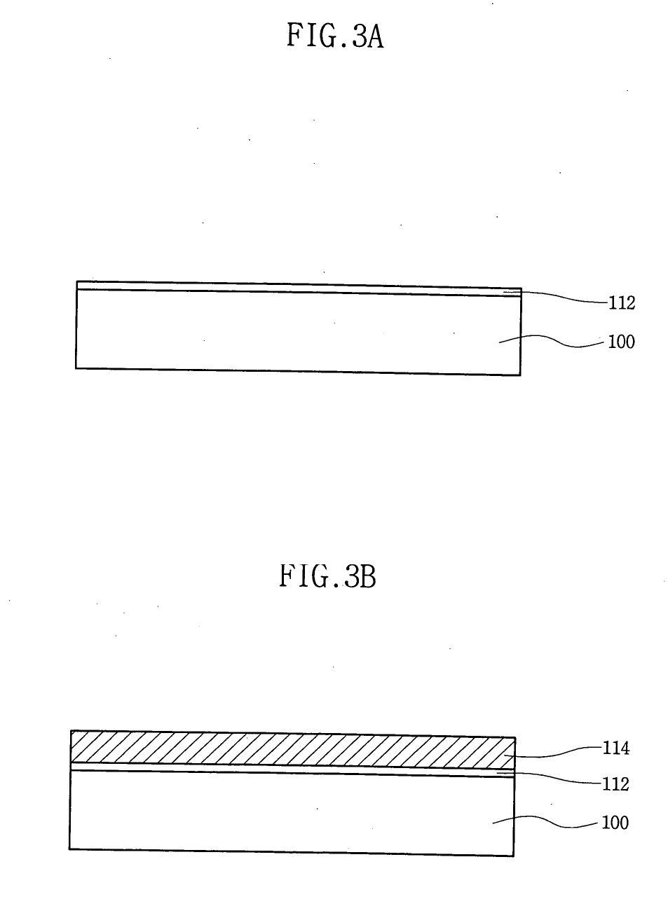

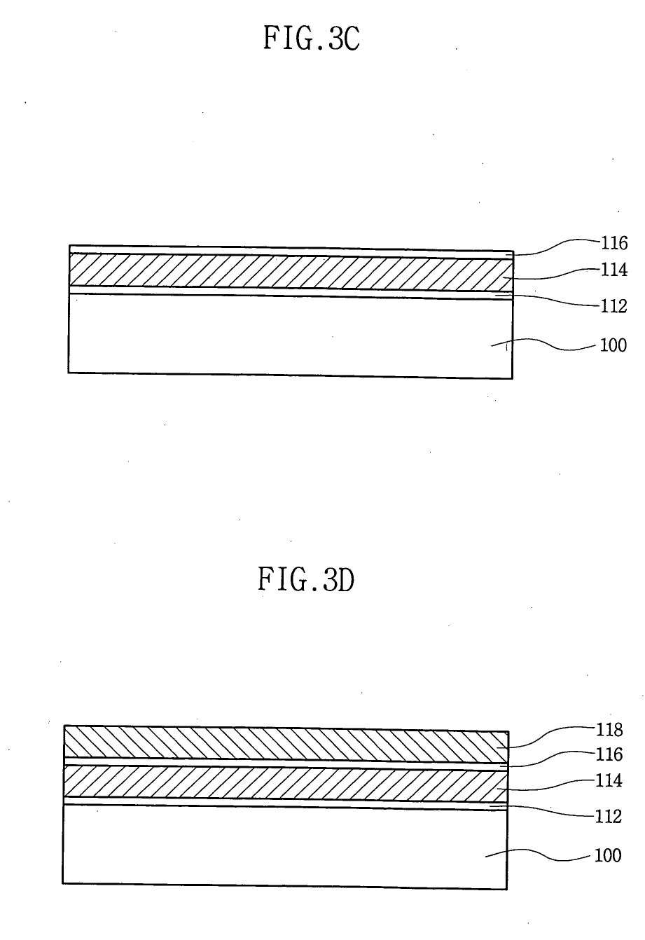

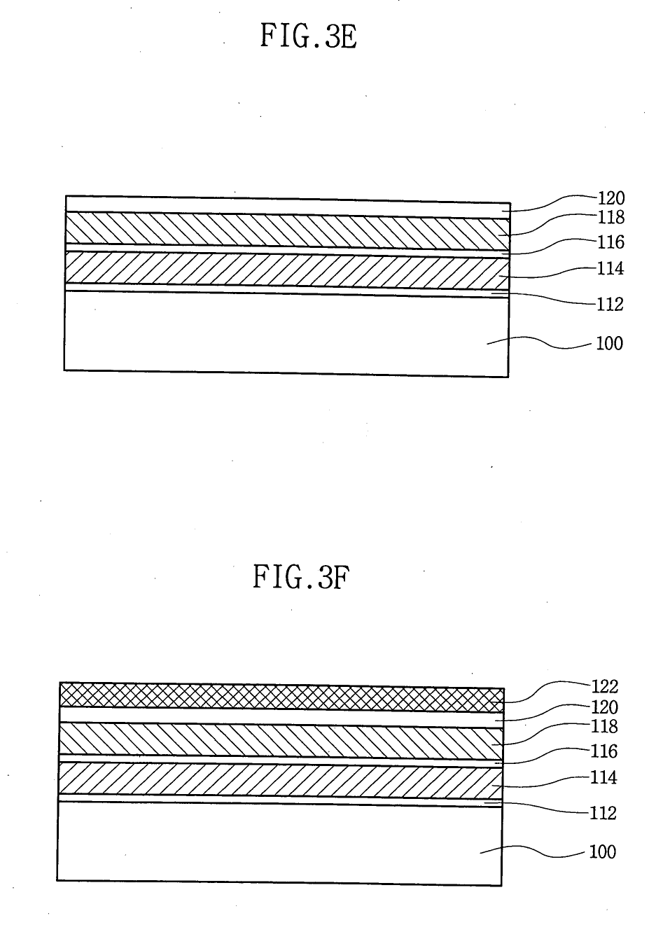

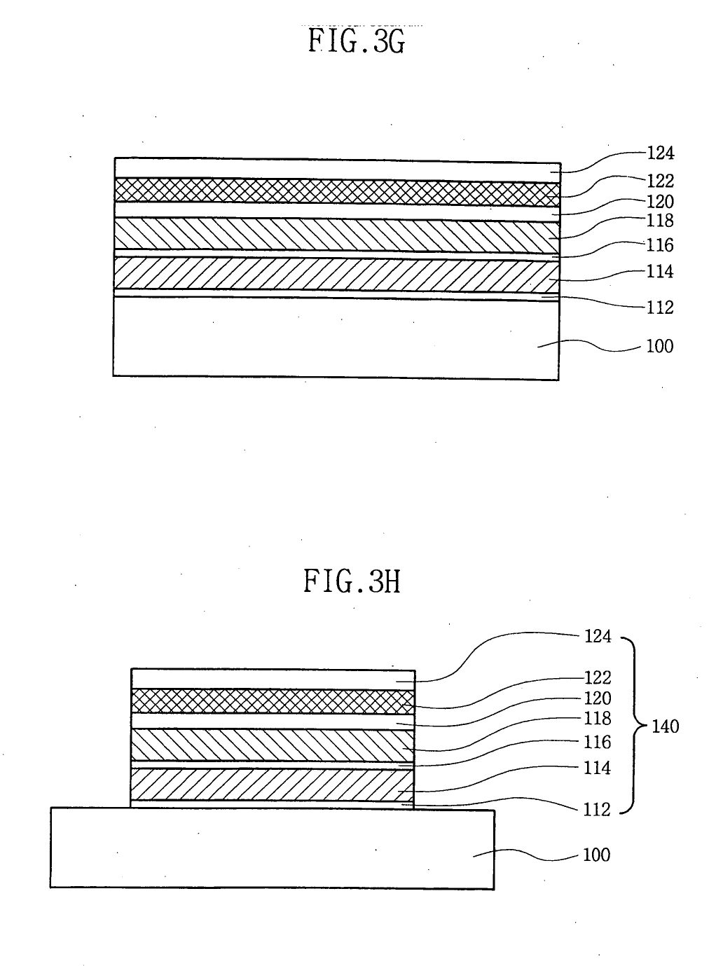

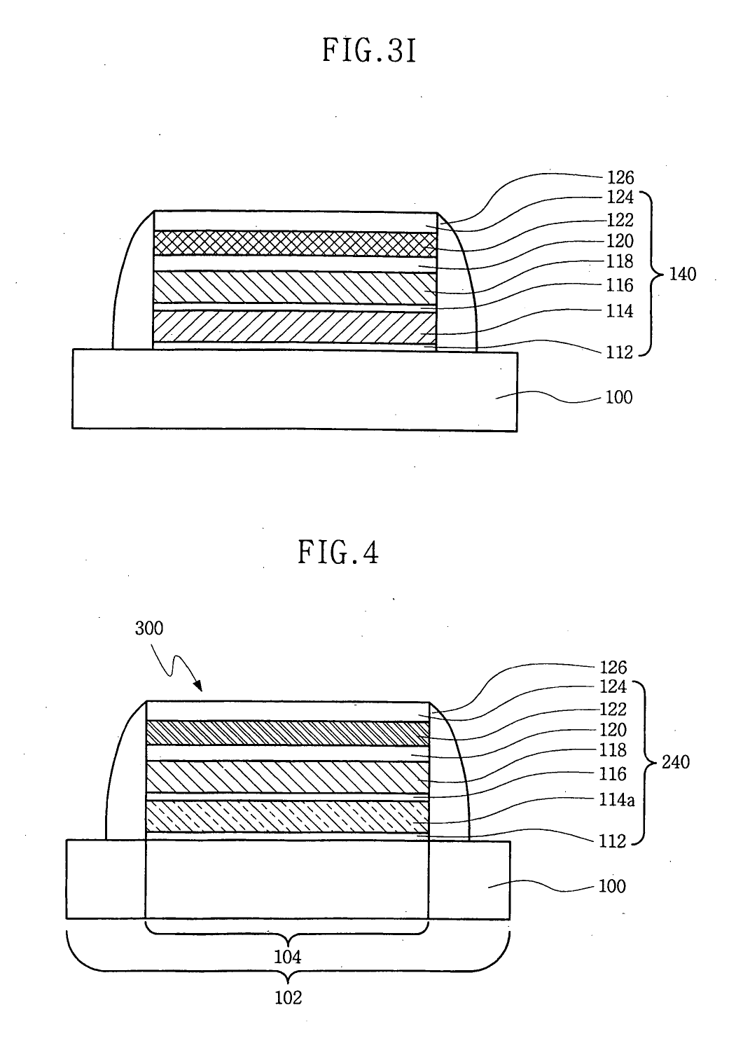

FIGS. 3A through 3I are cross-sectional views illustrating fabrication steps in a method for fabricating EEPROM cell transistor 200 in accordance with an embodiment of the invention.

As illustrated in FIG. 3A, first tunnel oxide layer 112 having a predetermined thickness is formed on semiconductor substrate 100. Semiconductor substrate 100 comprises an inactive region (not shown) in which an isolation layer (not shown) or a field oxide layer (not shown) is formed, and an active region 102 (see FIG. 2) that is defined and exposed by the isolation layer or field oxide layer. Active region 102 may, for example, be doped with p-type conductive impurities or n-type conductive impurities in order to improve electrical characteristics of EEPROM cell transistor 200. When the charge that tunnel through tunnel oxide layer 112 and are stored in first floating gate electrode 114 and second floating gate electrode 118 are electrons, active region 102 is preferably doped with p-type conductive impurities. Further, first tunnel oxide layer 112 is formed from silicon oxide using a rapid thermal process. First tunnel oxide layer 112 may be formed with a thickness of about 10 to 30 Å, for example.

As illustrated in FIG. 3B, first floating gate electrode 114 is formed on an entire upper surface of semiconductor substrate 100, on which first tunnel oxide layer 112 has been formed. In addition, first floating gate electrode 114 is formed from a phase changeable material and is formed with a predetermined thickness. In the embodiment illustrated in FIG. 3, first floating gate electrode 114 is formed from a phase changeable material comprising a GeSe or GeSeTe compound semiconductor material. The phase changeable material may be deposited using, for example, a chemical vapor deposition method or an atomic layer deposition method. Further, the phase changeable material may be deposited with a thickness of about 50 to 500 Å, for example.

As illustrated in FIG. 3C, second tunnel oxide layer 116 is formed on the entire upper surface of semiconductor substrate 100, on which first floating gate electrode 114 has been formed. In addition, second tunnel oxide layer 116 is formed from silicon oxide using a rapid thermal process or a chemical vapor deposition method. Second tunnel oxide layer 116 may be formed with a thickness of about 30 to 80 Å, for example.

As illustrated in FIG. 3D, second floating gate electrode 118 is formed on the entire upper surface of semiconductor substrate 100, on which second tunnel oxide layer 116 has been formed, and second floating gate electrode 118 is formed from a phase changeable material. In the embodiment illustrated in FIG. 3, second floating gate electrode 118 is formed from a phase changeable material comprising a GeSe or GeSeTe compound semiconductor material. The phase changeable material may be deposited using, for example, a chemical vapor deposition method or an atomic layer deposition method. When second floating gate electrode 118 is deposited, it is formed to have at thickness that is substantially the same as the thickness of first floating gate electrode 114. However, when second floating gate electrode 118 is formed from a phase changeable material in an amorphous state, second floating gate electrode 118 is preferably formed such that second floating gate electrode 118 is thinner than first floating gate electrode 114 so that the electric field induced by the voltage applied to control gate electrode 122, which will be formed subsequently, may be transferred to first floating gate electrode 114 without loss. The phase changeable material may be deposited, for example, with a thickness of about 30 to 400 Å.

As illustrated in FIG. 3E, gate insulating layer 120 is formed having a predetermined thickness and is formed on the entire upper surface of semiconductor substrate 100, on which second floating gate electrode 118 has been formed. In addition, gate insulating layer 120 is formed from a dielectric material that insulates second floating gate electrode 118 from control gate electrode 122 (which will be formed subsequently), and passes along an electric field induced by a voltage applied to control gate electrode 122. Gate insulating layer 120 may, for example, be formed from silicon oxide using a rapid thermal process or a chemical vapor deposition method, and may be formed with a thickness of about 50 to 120 Å.

Though it is not shown in the drawings, a photoresist layer is formed on gate insulating layer 120, and the photoresist layer is patterned to expose a portion of gate insulating layer 120 having a predetermined size. Next, by performing an etching process using the photoresist layer as an etching mask, the exposed portion of gate insulating layer 120 is removed to expose a portion of second floating gate electrode 118 and thereby form a contact hole. Then, the photoresist layer is removed.

Further, a conductive layer formed from a material such as titanium (Ti), tungsten (W), aluminum (Al), etc., may be formed to bury the contact hole, and semiconductor substrate 100 may be planarized to expose the portion of gate insulating layer 120 disposed below the conductive layer in order to form a contact plug that is formed in the contact hole formed in gate insulating layer 120 and exposed.

As illustrated in FIG. 3F, control gate electrode 122 having a predetermined thickness is formed on the entire upper surface of semiconductor substrate 100, on which gate insulating layer 120 has been formed. Control gate electrode 122 comprises at least one material selected from the group consisting of polysilicon doped with conductive impurities, tungsten, aluminum, and titanium. Control gate electrode 122 may be formed using, for example, a chemical vapor deposition method or physical vapor deposition method, and may be formed with a thickness of about 200 to 800 Å.

In an embodiment of the method in which a contact plug is formed inside the contact hole formed in gate insulating layer 120 to electrically connect control gate electrode 122 and second floating gate electrode 118, control gate electrode 122 may be formed such that the thickness of control gate electrode 122 is substantially the same everywhere it is formed on the upper surface of semiconductor substrate 100 (i.e., gate insulating layer 120 does not fill the contact hole). Alternatively, though it is not shown in the drawings, in an embodiment of the method in which a conductive layer is not formed to bury the contact hole as described previously, control gate electrode 122 may be formed with a predetermined thickness to bury the contact hole so that control gate electrode 122 will be electrically connected to second floating gate electrode 118, which is exposed by the contact hole formed in gate insulating layer 120.

As illustrated in FIG. 3G, a gate upper insulating layer 124 having a predetermined thickness is formed on the entire upper surface of semiconductor substrate 100, on which control gate electrode 122 has been formed. Gate upper insulating layer 124 may prevent control gate electrode 122 from being etched or damaged during a subsequent process for forming gate stack 140 (see FIG. 3H), spacers 126 (see FIG. 3I), or a pad contact electrode (not shown). Further, gate upper insulating layer 124 may insulate control gate electrode 122 from interconnection layers that will subsequently be formed on control gate electrode 122. Gate upper insulating layer 124 may be formed comprising, for example, silicon oxide or silicon nitride formed using a chemical vapor deposition method or a rapid thermal process. Further, the gate upper insulating layer 124 is formed with a thickness of about 300 to 1000 Å.

Referring to FIGS. 3G and 3H, a photoresist layer is deposited on the entire surface of semiconductor substrate 100, on which gate upper insulating layer 124 has been formed, and the photoresist layer is patterned to selectively expose portions of upper insulating layer 124 formed on the inactive region of semiconductor substrate 100, and portions of gate upper insulating layer 124 formed on source/drain regions, which are formed in active region 102. An etching process is then performed using the photoresist layer as an etching mask to sequentially remove portions of gate upper insulating layer 124, control gate electrode 122, gate insulating layer 120, second floating gate electrode 118, second tunnel oxide layer 116, first floating gate electrode 114, and first tunnel oxide layer 112. Then, the photoresist layer is removed to form gate stack 140 on channel region 104 (see FIG. 2).

Gate stack 140 may be formed through a dry etching process using a reaction gas having an excellent etching selectivity between various thin films among gate upper insulating layer 124, control gate electrode 122, gate insulating layer 120, second floating gate electrode 118, second tunnel oxide layer 116, first floating gate electrode 114, and first tunnel oxide layer 112, or interfaces between them. For example, the reaction gas used in the dry etching process may be strong acid such as HF, SF₆, etc., with respect to gate upper insulating layer 124, gate insulating layer 120, second tunnel oxide layer 116, and first tunnel oxide layer 112, which are formed from a silicon oxide layer, and may be weak acid such as a compound comprising CH₃ or H₂ with respect to control gate electrode 122, second floating gate electrode 118, and first floating gate electrode 114, which are formed from metal or a phase changeable material. In forming gate stack 140 using a dry etching process, an etch stop point is defined for each layer, and the dry etching process applied to each layer terminates at its etch stop point.

For example, a timed dry etching process may be performed using a reaction gas to sequentially remove gate upper insulating layer 124, control gate electrode 122, gate insulating layer 120, second floating gate electrode 118, second tunnel oxide layer 116, first floating gate electrode 114, and first tunnel oxide layer 112 formed on the source/drain regions formed in active region 102, and the inactive region of semiconductor substrate 100, to form gate stack 140 on channel region 104 of semiconductor substrate 100. The reaction gas used for the timed dry etching process may be, for example, a compound comprising CF₃.

In an alternative method of forming gate stack 140, a hard mask layer may be formed on the entire upper surface of semiconductor substrate 100, on which gate upper insulating layer 124 is formed, and photoresist may be deposited on the hard mask layer to form a photoresist layer. Then, the photoresist layer is patterned such that the portions of the hard mask layer that are formed on the inactive region of semiconductor substrate 100 and on the source/drain regions formed in active region 102 are exposed. An etching process may then be performed using the photoresist layer as an etching mask layer to remove portions of the hard mask layer to selectively expose gate upper insulating layer 124. The photoresist layer may then be removed and portions of gate upper insulating layer 124, control gate electrode 122, gate insulating layer 120, second floating gate electrode 118, second tunnel oxide layer 116, first floating gate electrode 114, and first tunnel oxide layer 112 that are exposed by the hard mask layer may be sequentially removed, thereby forming gate stack 140 on channel region 104. The hard mask layer may be removed through an etching process during the formation of gate stack 140.

Once gate stack 140 is formed, an ion implantation process may be performed using gate stack 140 as an ion implantation mask in order to implant impurities of second conductivity type into the source/drain regions exposed by gate stack 140 in order to form lightly-doped drain regions. The second conductivity type impurities have a conductivity type opposite that of first conductivity type impurities, with which channel region 104 of semiconductor substrate 100 has been doped.

As illustrated in FIG. 3I, spacers 126 are formed on the sidewalls of gate stack 140 in order to electrically insulate first and second floating gate electrodes 114 and 118, and control gate electrode 122. Spacers 126 are formed on the sidewalls of gate stack 140 to electrically insulate first and second floating gate electrodes 114 and 118, and control gate electrode 122 from the pad contact electrodes formed on the source/drain regions formed in active region 102. In an exemplary process for forming spacers 126, a silicon nitride layer may be formed on the entire surface of semiconductor substrate 100, on which gate stack 140 is formed, using a chemical vapor deposition process, and the silicon nitride layer may be isotropically etched to expose gate upper insulating layer 124. In the process described above, the silicon nitride layer may be formed such that the portions of the silicon nitride layer formed on the sidewalls of gate stack 140 are each thicker than the portion of the silicon nitride layer formed on the upper surface of gate stack 140. Then, all portions of the silicon nitride layer formed on the upper surface of semiconductor substrate 100 may be etched at substantially the same etching rate to form spacers 126 that are adapted to protect the sidewalls of gate stack 140.

Next, though it is not shown in the drawings, an ion implantation process is performed using spacers 126 and gate stack 140 as ion implantation masks to implant first conductive impurities (i.e., conductive impurities of the same type implanted into the lightly-doped drain regions) into the source/drain regions to thereby form source/drain impurity regions. Then, a conductive layer formed from, for example, tungsten or aluminum is formed on the entire upper surface of semiconductor substrate 100, in which the source/drain impurity regions are formed. Semiconductor substrate 100 is then planarized to expose gate upper insulating layer 124, thereby forming pad contact electrodes that are electrically insulated from gate stack 140 by spacers 126, and electrically connected to the source/drain impurity regions.

Thus, EEPROM cell transistor 200 in accordance with an embodiment of the invention comprises a plurality of floating gate electrodes, that is, first and second floating gate electrodes 114 and 118. First and second floating gate electrodes 114 and 118 are electrically insulated by first tunnel oxide layer 112, second tunnel oxide layer 116, and gate insulating layer 120 between active region 102 and control gate electrode 122, and are formed from a phase changeable material adapted to change between a crystalline state and an amorphous state in accordance with a voltage applied to control gate electrode 122. Because EEPROM cell transistor 200 has the structure described above, 2 or more bits more of data may be stored in and read from EEPROM cell transistor 200, thereby improving data storage capacity relative to a conventional EEPROM cell transistor.

FIG. 4 is a cross-sectional view illustrating the structure of an EEPROM cell transistor 300 in accordance with another embodiment of the invention.

As illustrated in FIG. 4, EEPROM cell transistor 300, in accordance with an embodiment of the invention, comprises a semiconductor substrate 100 having an active region 102 defined by an electrically insulated isolation layer (not shown) or an electrically insulated field oxide layer (not shown). Also, active region 102 comprises a channel region 104. EEPROM cell transistor 300 further comprises a first tunnel oxide layer 112 that is formed on semiconductor substrate 100 and has a predetermined thickness, a first floating gate electrode 114a formed from a conductive layer that has excellent conductivity and is formed on first tunnel oxide layer 112, and a second tunnel oxide layer 116 formed on first floating gate electrode 114a. EEPROM cell transistor 300 still further comprises a second floating gate electrode 118 formed from a phase changeable material (for example, GeSeTe) and formed on second tunnel oxide layer 116, a gate insulating layer 120 formed on second floating gate electrode 118, a control gate electrode 122 formed on gate insulating layer 120, and a gate upper insulating layer 124 that is formed on control gate electrode 122 and has a predetermined thickness. EEPROM cell transistor 300 further comprises spacers 126 formed on both sidewalls of a gate stack 240 comprising first and second floating gate electrodes 114a and 118, control gate electrode 122, first and second tunnel oxide layers 112 and 116, gate insulating layer 120, and upper insulating layer 124.

Though not shown in the drawings, a pad contact electrode may be formed on each side of gate stack 240, wherein each pad contact electrode is adjacent to a spacer 126 and is electrically connected to a source/drain region of EEPROM cell transistor 300 formed in active region 102.

First floating gate electrode 114a is formed from a conductive layer having excellent conductivity so that first floating gate electrode 114a may store charge that tunnel through first tunnel oxide layer 112 or permit the charge stored in first floating gate electrode 114a to tunnel through first tunnel oxide layer 112 to active region 102. The charge tunnel through first tunnel oxide layer 112 through an electric field induced by a predetermined voltage applied to control gate electrode 122. First floating gate electrode 114 may be, for example, formed of a conductive layer comprising at least one material selected from the group consisting of polysilicon doped with conductive impurities, tungsten, and aluminum. First floating gate electrode 114a of EEPROM cell transistor 200 and first floating gate electrode 114 of EEPROM cell transistor 200 are indicated in the drawings with different reference symbols because they are formed from different materials.

Second floating gate electrode 118 is formed from a phase changeable material that can change phases in accordance with a voltage applied to control gate electrode 122. The phase changeable material may be, for example, a GeSe compound semiconductor material or GeSeTe compound semiconductor material. The phase changeable material has been described previously with reference to FIG. 2, so further description of the phase changeable material will be omitted here.

When the phase changeable material of second floating gate electrode 118 is in a crystalline state, second floating gate electrode 118 can store charge that were previously stored in first floating gate electrode 114a that tunnel through second tunnel oxide layer 116 as a result of the electric field induced by the voltage applied to control gate electrode 122. First floating gate electrode 114a may store charge that tunnel from channel region 104 below gate stack 240 to first tunnel oxide layer 112.

In an exemplary data storage scheme for EEPROM cell transistor 300, when no charge are stored in either of first and second floating gate electrodes 114a and 118, EEPROM cell transistor 300 is storing a data value of “00,” and when charge are stored only in first floating gate electrode 114a, EEPROM cell transistor 300 is storing a data value of “01.” When charge are stored only in second floating gate electrode 118, EEPROM cell transistor 300 is storing a data value of “10,” and when charge are stored in both of first and second floating gate electrodes 114a and 118, EEPROM cell transistor 300 is storing a data value of “11.” Thus, used together, first and second floating gate electrodes 114a and 118 can store 2 bits of information.

Therefore, EEPROM cell transistor 300, in accordance with an embodiment of the invention, which comprises first floating gate electrode 114a formed from a conductive layer and insulated from channel region 104 and second floating gate electrode 118 formed from a phase changeable material and insulated from first floating gate electrode 114a, can store 2 or more bits of information, thereby improving data storage capacity.

Further, first floating gate electrode 114a formed on channel region 104 is formed from a conductive layer such as polysilicon doped with conductive impurities, and second floating gate electrode 118 is formed from a phase changeable material adapted to store a plurality of charge, so the material from which first and second floating gate electrodes 114a and 118 are formed is not limited to polysilicon doped with conductive impurities, unlike floating gate 14 of the conventional EEPROM cell transistor of FIG. 1. In addition, a process for reading data from EEPROM cell transistor 300 through a sense amplifier or page buffer can be simplified in comparison to the corresponding process for the conventional EEPROM transistor of FIG. 1.

In addition, first tunnel oxide layer 112 formed between active region 102 and first floating gate electrode 114a, second tunnel oxide layer 116 formed between first and second floating gate electrodes 114a and 118, and gate insulating layer 120 formed between second floating gate electrode 118 and control gate electrode 122 are formed from dielectric layers, such as a silicon oxide layers, that are adapted to pass the electric field induced by a voltage applied to control gate electrode 122.

First tunnel oxide layer 112 is disposed further from control gate electrode 122 than second tunnel oxide layer 116, and second tunnel oxide layer 116 is disposed further from control gate electrode 122 than gate insulating layer 120. Since the intensity of an electric field decreases as it passes through each of gate insulating layer 120, second tunnel oxide layer 116, and first tunnel oxide layer 112, which are each disposed sequentially further from control gate electrode 122, as described above, gate insulating layer 120, second tunnel oxide layer 116, and first tunnel oxide layer 112 are formed such that gate insulating layer 120 is thicker than second tunnel oxide layer 116, and second tunnel oxide layer 116 is thicker than first tunnel oxide layer 112. For example, first tunnel oxide layer 112 may be formed with a thickness of about 10 to 30 Å, second tunnel oxide layer 116 may be formed with a thickness of about 30 to 80 Å, and gate insulating layer 120 may be formed with a thickness of about 50 to 120 Å.

Further, since second floating gate electrode 118, which stores charge tunneling from first floating gate electrode 114a through second tunnel oxide layer 116, is formed from a different material than the material forming first floating gate electrode 114a, and amount of charge stored on first floating gate electrode 114a may be different from the amount of charge stored on second floating gate electrode 118. As a result, first and second floating gate electrodes 114a and 118 may store different data levels.

In addition, for example, first floating gate electrode 114a may be formed with a thickness of about 50 to 500 Å, and second floating gate electrode 118 may be formed with a thickness of about 30 to 400 Å.

Further, a predetermined voltage may be applied to control gate electrode 122 to permit charge stored in first and second floating gate electrodes 114a and 118 to tunnel to channel region 104. Also, the data stored in first floating gate electrode 114a and second floating gate electrode 118 can be read in accordance with a voltage applied between the source/drain regions of EEPROM cell transistor 300.

Also, charge (e.g., electrons) from channel region 104 may be stored in first floating gate electrode 114a by, for example, applying a predetermined first voltage (e.g., a positive voltage) to control gate electrode 122, which allows charge to tunnel from channel region 104, through first tunnel oxide layer 112, to first floating gate electrode 114a. Then, charge may be selectively stored in second floating gate electrode 118 by applying a second voltage higher than the first voltage to control gate electrode 122, which allows the charge stored in first floating gate electrode 114a to tunnel through second tunnel oxide layer 116 to second floating gate electrode 118. In the preceding example, first floating gate electrode 114a is formed from a conductive layer adapted to conduct the charge, and second floating gate electrode 118 is formed from a phase changeable material adapted to change between an amorphous state and a crystalline state, and second floating gate electrode 118 can store charge.

Thus, when writing data by selectively storing charge to second floating gate electrode 118, or when reading data using the charge selectively stored in second floating gate electrode 118, first floating gate electrode 114a must be formed from a conductive layer to store the charge.

In addition, when storing data by selectively storing charge in first floating gate electrode 114a, the phase changeable material of second floating gate electrode 118 must be in an amorphous state so that the electric field induced by the voltage applied to control gate electrode 122 directly reaches first floating gate electrode 114a through second floating gate electrode 118. That is, when the phase changeable material of second floating gate electrode 118 is in a crystalline state, floating gate electrode 118 acts as a conductive layer, so it is difficult for the electric field induced by a first voltage applied to control gate electrode 122 to pass through second floating gate electrode 118 and reach first floating gate electrode 114a. Thus, when the phase changeable material of second floating gate electrode 118 is in a crystalline state, data is not readily read by selectively using the charge stored in first floating gate electrode 114a.

Thus, the phase changeable material of first floating gate electrode 114a must be in a crystalline state when storing charge to second floating gate electrode 118 or using the charge stored in the second floating gate electrode 118 to read data.

Further, the phase changeable material of second floating gate electrode 118 must be in an amorphous state when storing charge to first floating gate electrode 114a or using the charge stored in first floating gate electrode 114a.

Control gate electrode 122 is formed from a conductive layer and is adapted to transfer a voltage that is externally applied or is applied from a control element (i.e., control part). For example, control gate electrode 122 may be formed from at least one material selected from the group consisting of polysilicon doped with conductive impurities, tungsten (W), aluminum (Al), and titanium (Ti).

Though it is not shown in the drawings, control gate electrode 122 may be formed so that it is electrically connected to second floating gate electrode 118 through a contact hole formed in gate insulating layer 120 that exposes a portion of second floating gate electrode 118. A material that fills the inside of the contact hole to electrically connect control gate electrode 122 and second floating gate electrode 118 may be formed from the material deposited during the formation of control gate electrode 122. Alternatively, silver (Ag) may be formed in the contact hole disposed between second floating gate electrode 118, which is formed from the phase changeable material, and control gate electrode 122 in order to improve electrical characteristics of the connection between second floating gate electrode 118 and control gate electrode 122. Further, a separate process for forming a contact plug, in which a conductive layer is deposited inside the contact hole and then planarized, may be performed to form the contact plug. The contact plug may be formed from silver (Ag), for example, which has excellent conductivity.

Second floating gate electrode 118, which is electrically connected to control gate electrode 122, is formed from a phase changeable material adapted to change between an amorphous state and a crystalline state in accordance with a voltage applied to control gate electrode 122. As described above, in order to store charge to first floating gate electrode 114a or to permit charge to tunnel through first tunnel oxide layer 112 to channel region 104, the phase changeable material of second floating gate electrode 118 must be in an amorphous state and function as a dielectric layer. Further, second floating gate electrode 118 must be formed from a phase changeable material adapted to change from an amorphous state to a crystalline state in accordance with the application of a predetermined voltage for a predetermined amount of time in order to store charge tunneling through second tunnel oxide layer 116 to second floating gate electrode 118 without excessively storing charge to first floating gate electrode 114a.

Thus, EEPROM cell transistor 300 in accordance with an embodiment of the invention comprises first floating gate electrode 114a and second floating gate electrode 118. First floating gate electrode 114a is insulated between channel region 104 and control gate electrode 122, is formed from a conductive layer, and is formed on channel region 104. Second floating gate electrode 118 is insulated from first floating gate electrode 114a and is formed from a phase changeable material. Because EEPROM cell transistor 300 has the structure described above, EEPROM cell transistor 300 can store 2 or more bits of data, thereby increasing the data storage capacity relative to a conventional EEPROM cell transistor.

Hereinafter, a method of fabricating EEPROM cell transistor 300 in accordance with an embodiment of the invention will be described.

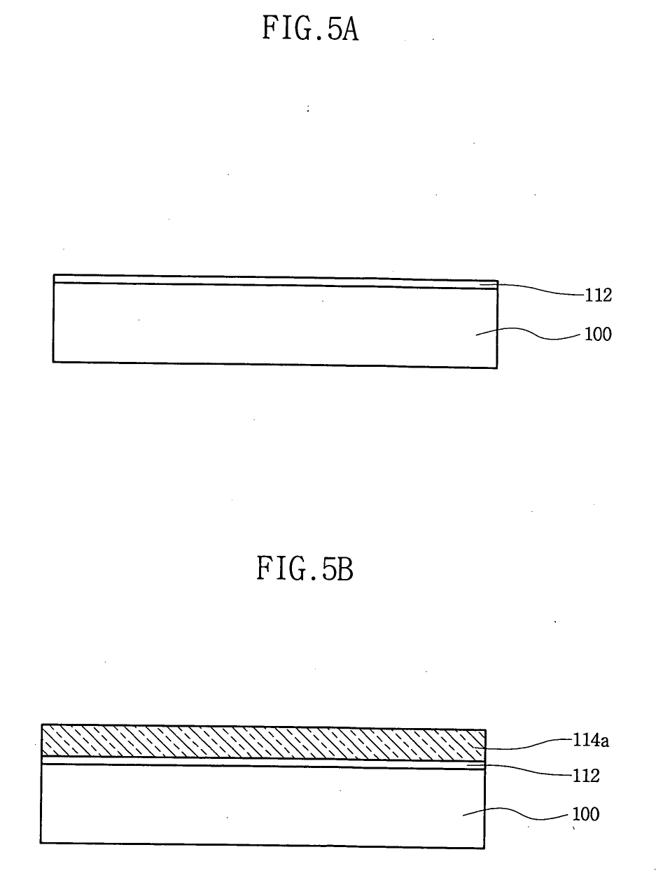

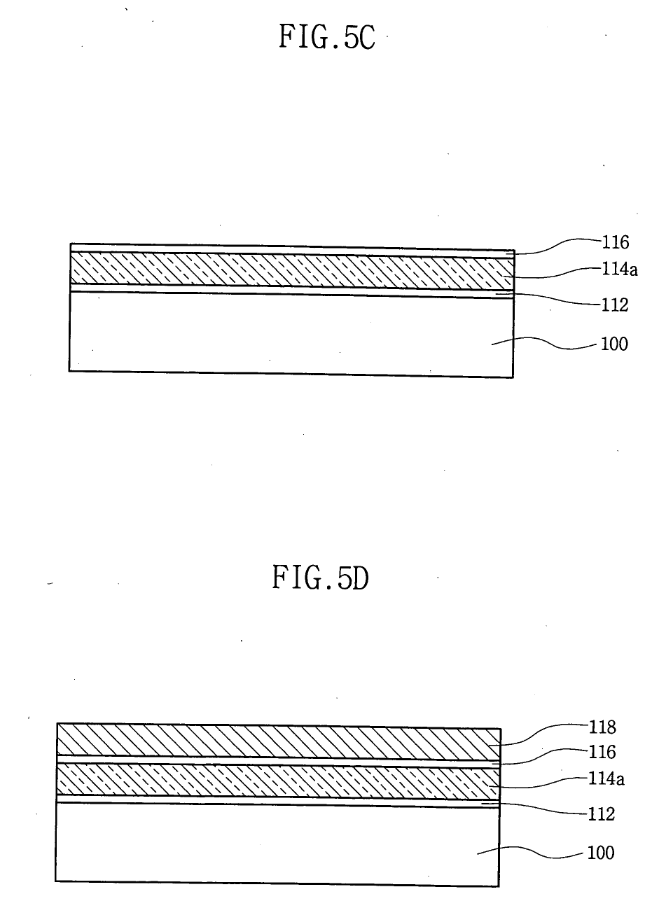

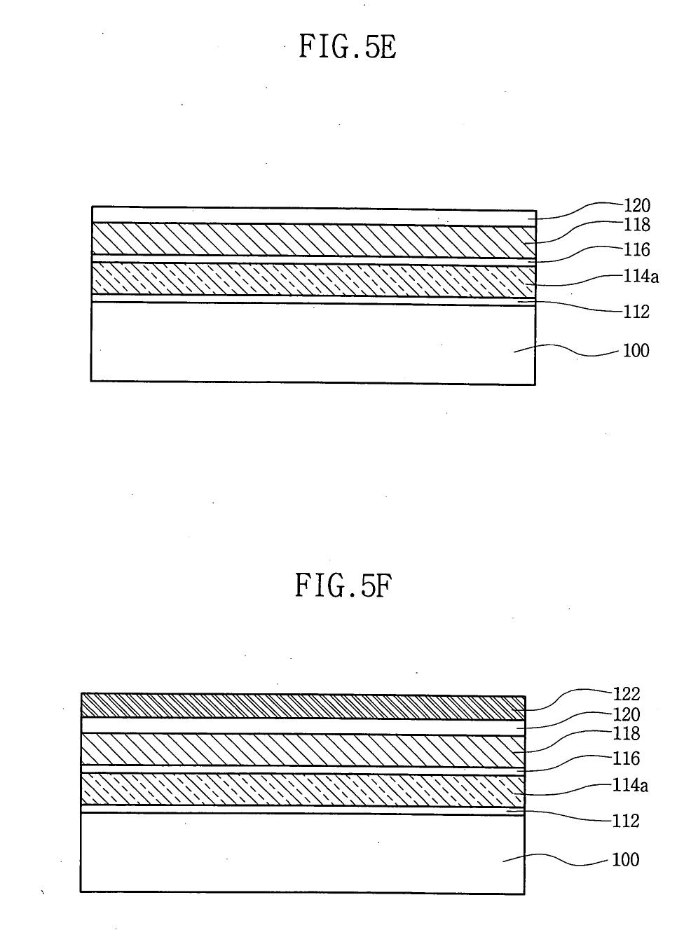

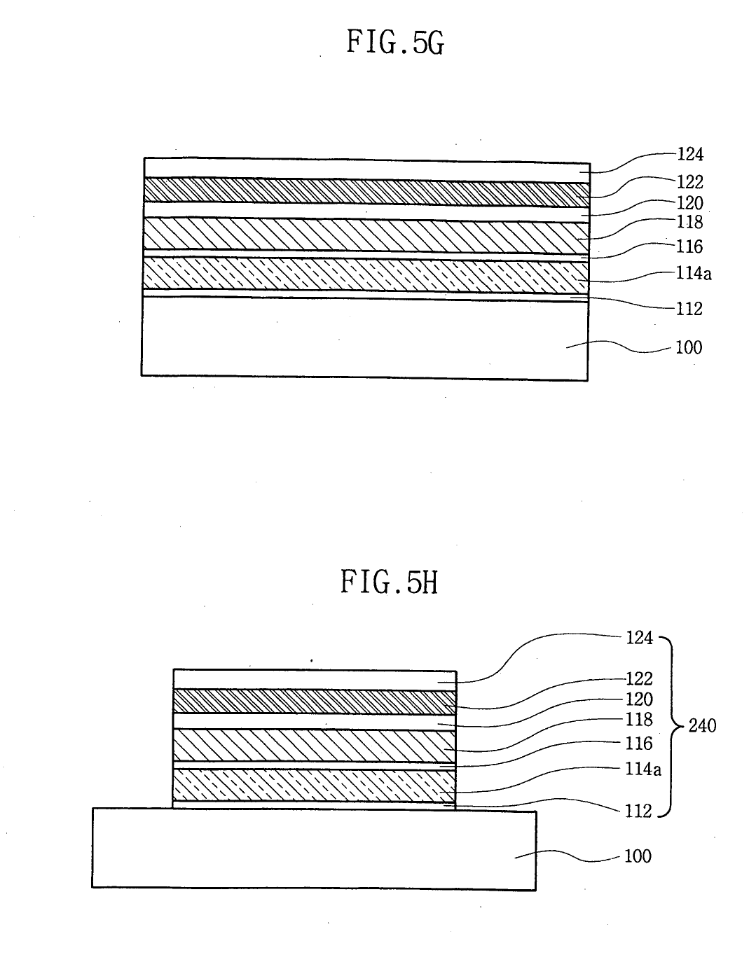

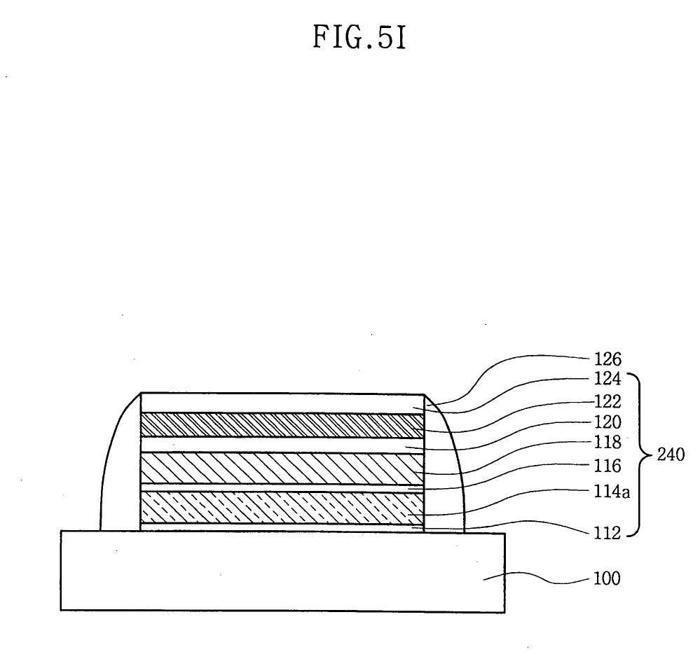

FIGS. 5A through 5I are cross-sectional views illustrating fabrication steps in a method for fabricating EEPROM cell transistor 300 in accordance with an embodiment of the invention.

As illustrated in FIG. 5A, first tunnel oxide layer 112 having a predetermined thickness is formed on a semiconductor substrate 100. Semiconductor substrate 100 comprises an inactive region (not shown) having an isolation layer (not shown) or a field oxide layer (not shown), and active region 102 (see FIG. 4) defined by the isolation layer or the field oxide layer. Active region 102 may, for example, be doped with p-type conductive impurities or n-type conductive impurities. When the charge that tunnel through tunnel oxide layer 112 and are stored in first floating gate electrode 114a and second floating gate electrode 118 are electrons, active region 102 is preferably doped with p-type conductive impurities. Further, first tunnel oxide layer 112 is formed from silicon oxide using a rapid thermal process. First tunnel oxide layer 112 may be formed with a thickness of about 10 to 30 Å, for example.

As illustrated in FIG. 5B, first floating gate electrode 114a is formed on an entire upper surface of semiconductor substrate 100, on which first tunnel oxide layer 112 has been formed. In addition, first floating gate electrode 114a is formed from a conductive material and is formed with a predetermined thickness. In the embodiment illustrated in FIG. 5, first floating gate electrode 114a is formed from a conductive layer comprising at least one material selected from the group consisting of polysilicon doped with conductive impurities, tungsten (W), and aluminum (Al).

As illustrated in FIG. 5C, second tunnel oxide layer 116 is formed on the entire upper surface of semiconductor substrate 100, on which first floating gate electrode 114a has been formed. In addition, second tunnel oxide layer 116 is formed from silicon oxide using a rapid thermal process or a chemical vapor deposition method. Second tunnel oxide layer 116 may be formed with a thickness of about 30 to 80 Å, for example.

As illustrated in FIG. 5D, second floating gate electrode 118 is formed on the entire upper surface of semiconductor substrate 100, on which second tunnel oxide layer 116 has been formed, and second floating gate electrode 118 is formed from a phase changeable material. In the embodiment illustrated in FIG. 5, second floating gate electrode 118 is formed from a phase changeable material comprising a GeSe or a GeSeTe compound semiconductor material. The phase changeable material may be formed using, for example, a chemical vapor deposition method or an atomic layer deposition method. Since first floating gate electrode 114a and second floating gate electrode 118 are each formed from different materials, their thicknesses can be determined by respective amounts of charge to be stored in first floating gate electrode 114a and second floating gate electrode 118. Further, when second floating gate electrode 118 is formed from a phase changeable material in an amorphous state, second floating gate electrode 118 is preferable formed such that second floating gate electrode 118 is thinner than first floating gate electrode 114a so that the electric field induced by the voltage applied to control gate electrode 122, which will be formed subsequently, may be transferred to first floating gate electrode 114a without loss. Second floating gate electrode 118 may be formed with a thickness of about 30 to 400 Å, for example.

As illustrated in FIG. 5E, gate insulating layer 120 is formed having a predetermined thickness and is formed on the entire upper surface of semiconductor substrate 100, on which second floating gate electrode 118 has been formed. In addition, gate insulating layer 120 is formed from a dielectric material that insulates second floating gate electrode 118 from control gate electrode 122 (which will be formed subsequently), and passes along an electric field induced by a voltage applied to control gate electrode 122. Gate insulating layer 120 may, for example, be formed from silicon oxide using a rapid thermal process or a chemical vapor deposition method, and may be formed with a thickness of about 50 to 120 Å.

Though it is not shown in the drawings, a photoresist layer is formed on gate insulating layer 120, and the photoresist layer is patterned to expose a portion of gate insulating layer 120 having a predetermined size. Next, by performing an etching process using the photoresist layer as an etching mask, the exposed portion of gate insulating layer 120 is removed to expose a portion of second floating gate electrode 118 and thereby form a contact hole. Then, the photoresist layer is removed.

Further, a conductive layer formed from a material such as titanium (Ti), tungsten (W), aluminum (Al), etc., may be formed to bury the contact hole, and semiconductor substrate 100 may be planarized to expose the portion of gate insulating layer 120 disposed below the conductive layer in order to form a contact plug that is formed in the contact hole formed in gate insulating layer 120 and exposed.

As illustrated in FIG. 5F, control gate electrode 122 having a predetermined thickness is formed on the entire upper surface of semiconductor substrate 100, on which gate insulating layer 120 has been formed. Control gate electrode 122 comprises at least one material selected from the group consisting of polysilicon doped with conductive impurities, tungsten, aluminum, and titanium. Control gate electrode 122 may be formed using, for example, a chemical vapor deposition method or physical vapor deposition method, and may be formed with a thickness of about 200 to 800 Å.

In an embodiment of the method in which a contact plug is formed inside the contact hole formed in gate insulating layer 120 to electrically connect control gate electrode 122 and second floating gate electrode 118, control gate electrode 122 may be formed such that the thickness of control gate electrode 122 is substantially the same everywhere it is formed on the upper surface of semiconductor substrate 100 (i.e., gate insulating layer 120 does not fill the contact hole). Alternatively, though it is not shown in the drawings, in an embodiment of the method in which a conductive layer is not formed to bury the contact hole as described previously, control gate electrode 122 may be formed with a predetermined thickness to bury the contact hole so that control gate electrode 122 will be electrically connected to second floating gate electrode 118, which is exposed by the contact hole formed in gate insulating layer 120.

As illustrated in FIG. 5G, a gate upper insulating layer 124 having a predetermined thickness is formed on the entire upper surface of semiconductor substrate 100, on which control gate electrode 122 has been formed. Gate upper insulating layer 124 may prevent control gate electrode 122 from being etched or damaged during a subsequent process for forming gate stack 240 (see FIG. 5H), spacers 126 (see FIG. 5I), or a pad contact electrode (not shown). Further, gate upper insulating layer 124 may insulate control gate electrode 122 from interconnection layers that will subsequently be formed on control gate electrode 122. Gate upper insulating layer 124 may be formed comprising, for example, silicon oxide or silicon nitride formed using a chemical vapor deposition method or a rapid thermal process. Further, the gate upper insulating layer 124 is formed with a thickness of about 300 to 1000 Å.

Referring to FIGS. 5G and 5H, a photoresist layer is deposited on the entire surface of semiconductor substrate 100, on which gate upper insulating layer 124 has been formed, and the photoresist layer is patterned to selectively expose portions of upper insulating layer 124 formed on the inactive region of semiconductor substrate 100, and portions of gate upper insulating layer 124 formed on source/drain regions, which are formed in active region 102. An etching process is then performed using the photoresist layer as an etching mask to sequentially remove portions of gate upper insulating layer 124, control gate electrode 122, gate insulating layer 120, second floating gate electrode 118, second tunnel oxide layer 116, first floating gate electrode 114a, and first tunnel oxide layer 112. Then, the photoresist layer is removed to form gate stack 240 on channel region 104 (see FIG. 4).

Gate stack 240 may be formed through a dry etching process using a reaction gas having an excellent etching selectivity between various thin films among gate upper insulating layer 124, control gate electrode 122, gate insulating layer 120, second floating gate electrode 118, second tunnel oxide layer 116, first floating gate electrode 114a, and first tunnel oxide layer 112, or interfaces between them. For example, the reaction gas used in the dry etching process may be strong acid such as HF, SF₆, etc., with respect to gate upper insulating layer 124, gate insulating layer 120, second tunnel oxide layer 116, and first tunnel oxide layer 112, which are formed from a silicon oxide layer, and may be weak acid such as a compound comprising CH₃ or H₂ with respect to control gate electrode 122, second floating gate electrode 118, and first floating gate electrode 114a, which are formed from metal or a phase changeable material. In forming gate stack 240 through a dry etching process as described previously, an etch stop point is defined for each layer, and an associated dry etching process proceeds to that point.

Then, a timed dry etching process is performed using a reaction gas sequentially remove gate upper insulating layer 124, control gate electrode 122, gate insulating layer 120, second floating gate electrode 118, second tunnel oxide layer 116, first floating gate electrode 114a, and first tunnel oxide layer 112 formed on the source/drain regions formed in active region 102, and the inactive region of semiconductor substrate 100, to form gate stack 240 on channel region 104. The reaction gas used for the timed dry etching process may be, for example, a compound comprising CF₃.

Though it is not shown in the drawings, in an alternative method for forming gate stack 240, a hard mask layer may be formed on the entire upper surface of semiconductor substrate 100, on which gate upper insulating layer 124 is formed, and photoresist may be deposited on the hard mask layer to form a photoresist layer. Then, the photoresist layer is patterned such that the portions of the hard mask layer that are formed on the inactive region of semiconductor substrate 100 and on the source/drain regions formed in active region 102 are exposed. An etching process may then be performed using the photoresist layer as an etching mask layer to remove portions of the hard mask layer to selectively expose gate upper insulating layer 124. The photoresist layer may then be removed and portions of gate upper insulating layer 124, control gate electrode 122, gate insulating layer 120, second floating gate electrode 118, second tunnel oxide layer 116, first floating gate electrode 114a, and first tunnel oxide layer 112 that are exposed by the hard mask layer may be sequentially removed, thereby forming gate stack 240 on channel region 104. The hard mask layer may be removed through an etching process during the formation of gate stack 240.

Though it is not shown in the drawings, once gate stack 240 is formed, an ion implantation process may then be performed using gate stack 240 as an ion implantation mask in order to implant second conductive impurities (i.e., conductive impurities of a second type) into the source/drain regions exposed by gate stack 240 in order to form lightly-doped drain regions. The second conductive impurities have a conductivity type opposite that of first conductive impurities (i.e., conductive impurities of a first type), with which channel region 104 has been doped.

As illustrated in FIG. 5I, spacers 126 are formed on the sidewalls of gate stack 240 in order to electrically insulate first and second floating gate electrodes 114a and 118, and control gate electrode 122. Spacers 126 are formed on the sidewalls of gate stack 240 to electrically insulate first and second floating gate electrodes 114a and 118, and control gate electrode 122 from the pad contact electrodes formed on the source/drain regions formed in active region 102. In an exemplary process for forming spacers 126, a silicon nitride layer may be formed on the entire surface of semiconductor substrate 100, on which gate stack 240 is formed, using a chemical vapor deposition process, and the silicon nitride layer may be isotropically etched to expose gate upper insulating layer 124. In the process described above, the silicon nitride layer may be formed such that the portions of the silicon nitride layer formed on the sidewalls of gate stack 240 are each thicker than the portion of the silicon nitride layer formed on the upper surface of gate stack 240. Then, all portions of the silicon nitride layer formed on the upper surface of semiconductor substrate 100 may be etched at substantially the same etching rate to form spacers 126 that are adapted to protect the sidewalls of gate stack 240.

Next, an ion implantation process is performed using spacers 126 and gate stack 240 as ion implantation masks to implant first conductive impurities (i.e., conductive impurities of the same type implanted into the lightly-doped drain regions) into the source/drain regions to thereby form source/drain impurity regions. Then, a conductive layer formed from, for example, tungsten or aluminum is formed on the entire upper surface of semiconductor substrate 100, in which the source/drain impurity regions are formed. Semiconductor substrate 100 is then planarized to expose gate upper insulating layer 124, thereby forming pad contact electrodes that are electrically insulated from gate stack 240 by spacers 126, and electrically connected to the source/drain impurity regions.

Therefore, EEPROM cell transistor 300, in accordance with an embodiment of the invention, comprises first floating gate electrode 114a, which is formed from a conductive layer, and second floating gate electrode 118 that is insulated from first floating gate electrode 114a and formed from a phase changeable material, and stores 2 or more bits of data, thereby increasing the data storage capacity relative to a conventional EEPROM cell transistor.

Thus, as described previously, an EEPROM cell transistor in accordance with an embodiment of the invention comprises a first floating gate electrode and a second floating gate electrode. The first floating gate electrode is insulated between the active region of a semiconductor substrate and a control gate electrode, is formed from a phase changeable material or a conductive layer, and is formed on channel region 104. The second floating gate electrode is insulated from the first floating gate electrode, and formed from a phase changeable material. Because the EEPROM cell transistor in accordance with an embodiment of the invention has the structure described above, the EEPROM cell transistor can store 2 or more bits of information, so the data storage capacity of the EEPROM cell transistor can be increased relative to that of the conventional EEPROM cell transistor.

Further, since the EEPROM cell transistor in accordance with an embodiment of the invention comprises at least one floating gate electrode formed from a phase changeable material, the material from which the floating gate electrode is formed not limited to polysilicon doped with conductive impurities. In addition, a process for reading data from the EEPROM cell transistor through a sense amplifier or page buffer can be simplified.

Though embodiments of the invention have been described herein, it will be understood that the scope of the invention is not limited to the disclosed embodiments. Rather, various modifications to the embodiments and alternative arrangements that are within the capabilities of one skilled in the art are within the scope of the invention as defined by the accompanying claims.

What is claimed is:

1. An electrically erasable programmable read-only memory (EEPROM) cell transistor comprising:
a first tunnel oxide layer disposed on a semiconductor substrate;
a first floating gate electrode disposed on the first tunnel oxide layer and adapted to store charge tunneling through the first tunnel oxide layer;
a second tunnel oxide layer disposed on the first floating gate electrode;
a second floating gate electrode disposed on the second tunnel oxide layer and adapted to store charge tunneling from the first floating gate electrode through the second tunnel oxide layer, wherein the second floating gate electrode is formed from a phase changeable material;
a gate insulating layer disposed on the second floating gate electrode; and,
a control gate electrode disposed on the gate insulating layer.

2. The EEPROM cell transistor of claim 1, wherein the first floating gate electrode is formed from a phase changeable material or a conductive layer.

3. The EEPROM cell transistor of claim 2, wherein the conductive layer comprises doped polysilicon.

4. The EEPROM cell transistor of claim 2, wherein the phase changeable material forming either one of the first or second floating gate electrodes comprises a GeSe compound semiconductor material or a GeSeTe compound semiconductor material.

5. The EEPROM cell transistor of claim 4, wherein the first floating gate electrode is thicker than the second floating gate electrode.

6. The EEPROM cell transistor of claim 4, wherein:
the phase changeable material forming the first floating gate electrode is set in accordance with application of a first set voltage having at least a first set voltage level;
the phase changeable material forming the second floating gate electrode is set in accordance with application of a second set voltage having at least a second set voltage level; and,
the first set voltage level is a lower than the second set voltage level.

7. The EEPROM cell transistor of claim 6, wherein:
the phase changeable material forming the second floating gate electrode is set when the second set voltage is applied to the second floating gate for a second amount of time;
the phase changeable material forming the second floating gate electrode is reset when a second reset voltage having at least a second reset voltage level is applied to the second floating gate for a first amount of time; and,
the second amount of time is greater than the first amount of time.

8. The EEPROM cell transistor of claim 4, wherein:
the phase changeable material forming the first floating gate electrode is reset when a first reset voltage having at least a first reset voltage level is applied to the first floating gate electrode;
the phase changeable material forming the second floating gate electrode is reset when a second reset voltage having at least a second reset voltage is applied to the second floating gate electrode; and,
the first reset voltage level is substantially the same as the second reset voltage level.

9. The EEPROM cell transistor of claim 1, wherein the first floating gate electrode has a thickness in a range of 50 to 500 Å.

10. The EEPROM cell transistor of claim 1, wherein the second floating gate electrode has a thickness in a range of 30 to 400 Å.

11. The EEPROM cell transistor of claim 1, wherein the first tunnel oxide layer has a thickness in a range of 10 to 30 Å.

12. The EEPROM cell transistor of claim 1, wherein the second tunnel oxide layer has a thickness in a range of 30 to 80 Å.

13. The EEPROM cell transistor of claim 1, wherein the gate insulating layer has a thickness in a range of 50 to 120 Å.

14. The EEPROM cell transistor of claim 1, wherein the control gate electrode comprises at least one material selected from the group consisting of polysilicon doped with conductive impurities, tungsten (W), aluminum (Al), and titanium (Ti).

15. The EEPROM cell transistor of claim 1, further comprising:
a contact hole formed in the gate insulating layer; and,
a contact plug disposed in the contact hole,
wherein the control gate electrode is electrically connected to the second floating gate via the contact plug.

16. The EEPROM cell transistor of claim 15, wherein the contact plug comprises silver.

17. The EEPROM cell transistor of claim 1, further comprising:
a contact hole formed in the gate insulating layer;
a first material filling the contact hole and adapted to electrically connect the control gate electrode to the second floating gate electrode,
wherein the control gate electrode is formed from the first material.

18. A method for fabricating an EEPROM cell transistor comprising:
forming a first tunnel oxide layer on a semiconductor substrate;
forming a first floating gate electrode on the first tunnel oxide layer, wherein the first floating gate electrode is formed from a phase changeable material or metal;
forming a second tunnel oxide layer on the first floating gate electrode;
forming a second floating gate electrode on the second tunnel oxide layer, wherein the second floating gate electrode is formed from a phase changeable material;
forming a gate insulating layer on the second floating gate electrode; and,
forming a control gate electrode on the gate insulating layer.

19. The method of claim 18, further comprising:
removing a portion of the gate insulating layer over a channel region to form a contact hole exposing a portion of the second floating gate electrode; and,
forming a contact plug in the contact hole to electrically connect the control gate electrode and the second floating gate electrode.

20. The method of claim 18, further comprising:
removing a portion of the gate insulating layer over a channel region to form a contact hole that exposes a portion of the second floating gate electrode; and,
filling the contact hole with a first material to electrically connect the control gate electrode and the second floating gate electrode,
wherein the control gate electrode is formed from the first material.

21. The method of claim 18, further comprising forming a gate upper insulating layer on the control gate electrode.

22. The method of claim 18, further comprising:
partially removing each of the gate upper insulating layer, the control gate electrode, the gate insulating layer, the second floating gate electrode, the second tunnel oxide layer, the first floating gate electrode, and the first tunnel oxide layer to form a gate stack; and,
forming spacers on sidewalls of the gate stack.
